(19) United States
(12) Patent Application Publication
(10) Pub. No.: US 2009/0134016 A1
(43) Pub. Date: May 28, 2009

(54) UNDERBUMP METALLURGY EMPLOYING SPUTTER-DEPOSITED NICKEL TITANIUM COPPER ALLOY

(75) Inventors: Luc Belanger, Granby (CA); Srinivasa S.N. Reddy, Lagrangeville, NY (US); Brian R. Sundlof, Beacon, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/946,231

(22) Filed: Nov. 28, 2007

(51) Int. Cl. C23C 14/00

(52) U.S. Cl. 204/192.25

(57) ABSTRACT

A metallic adhesion layer is formed on a last level metal plate exposed in an opening of a passivation layer. A Ni—Cu alloy in which the weight percentage of Ni is from about 50% to about 70% is deposited by sputtering onto the metallic adhesion layer to form an underbump metallic layer. Optionally, a wetting layer comprising Cu or Au may be deposited by sputtering. A C4 ball is applied to a surface of the underbump metallic layer comprising the Ni—Cu alloy or the wetting layer for C4 processing. The sputter deposition of the Ni—Cu alloy offers economic advantages relative to known methods in the art since the Ni—Cu alloy in the composition of the present invention is non-magnetic and easy to sputter, and the consumption of the inventive Ni—Cu alloy is limited during C4 processing.

### RELATED APPLICATIONS

The present application is related to a co-pending U.S. patent application Ser. No. ______ (Attorney Docket No. FIS920070247US1 (SSMP 21268)), which is incorporated herein by reference.

### FIELD OF THE INVENTION

The present invention relates to semiconductor structures, and particularly to underbump metallurgy (UBM) employing a sputter-deposited nickel copper alloy, and structures and methods thereof.

### BACKGROUND OF THE INVENTION

Once formation of semiconductor devices and interconnects on a semiconductor wafer (substrate) is completed, the semiconductor wafer is diced into semiconductor chips, or “dies.” Functional semiconductor chips are then packaged to facilitate mounting on a circuit board. A package is a supporting element for the semiconductor chip that provides mechanical protection and electrical connection to an upper level assembly system such as the circuit board. One typical packaging technology is Controlled Collapse Chip Connection (C4) packaging, which employs C4 balls each of which contacts a C4 pad on the semiconductor chip and another C4 pad on a packaging substrate. The packaging substrate may then be assembled on the circuit board.

Thus, the packaging substrate facilitates formation of an electrical link between the semiconductor chip and a system board of a computer. A semiconductor chip is mounted on a die foot print area located on a top surface of the packaging substrate. The die foot print area contains C4 pads on which a semiconductor chip may be attached by C4 bonding.

A typical semiconductor chip employing a packaging substrate may comprise about 5,000 input/output nodes. Each of these nodes are electrically connected to a C4 pad on a top surface of the semiconductor chip in a two dimensional array. Typical two dimensional array configurations for the C4 pads include 4 on 8 configuration, which employs C4 solder balls having a diameter of 4 mils (approximately 100 microns) and a pitch of 8 mils (approximately 200 microns) in a rectangular array, and 3.0 on 6 configuration, which employs C4 solder balls having a diameter of 3.0 mils (approximately 75 microns) and a pitch of 6 mils (approximately 150 microns) in a rectangular array. Thus, more than 5,000 C4 solder balls may be formed on the semiconductor chip, which may be typically about 2 cm×2 cm in size.

The collection of metallic layers employed to attach a C4 ball to a semiconductor chip is called an “underbump metallurgy structure,” or a “UBM structure” in the art. A typical underbump metallurgy structure includes a stack of a metallic adhesion layer, an underbump metallic layer, and an optional wetting layer. The metallic adhesion layer is formed directly on the semiconductor chip and comprises an adhesion promoting metallic material such as Ti, TiW, or TiN. The underbump metallic layer may comprise an elemental metal such as Cu or Ni, which may be deposited by electroplating or by sputtering. Alternately, the underbump metallic layer may comprise a metal compound such as a Ni—Si alloy or a Ni—W alloy or Ni—V alloy, which may be deposited only by sputtering since electroplating of an alloy faces technical difficulties. In case the underbump metallic layer comprises any other material than pure elemental Cu or pure elemental Ni or Cu—Ni alloy, a wetting layer is needed to promote adhesion of a C4 ball with the underbump metallic layer. The wetting layer typically comprises elemental Cu or elemental Au or Ag.

While formation of an underbump metallic layer comprising pure elemental Cu or pure elemental Ni by electroplating or sputtering may seem to be the most inexpensive method of forming the underbump metallic layer, both choices have inherent disadvantages. Pure elemental Cu is known to react readily with lead-free C4 balls. About 2.5 μm to 5 μm of pure elemental Cu is consumed in a reaction with a C4 ball in a typical C4 bonding process. Due to such high consumption rate of Cu, a thick Cu film is required for the underbump metallic layer.

In the case of pure elemental Ni, the amount of consumption in a reaction with a C4 ball is less than pure elemental Cu, and may be from about 1.0 μm to abut 2.0 μm. However, pure Ni is magnetic and renders sputtering of Ni technically difficult. Thus, deposition of pure elemental Ni is almost always performed by electroplating in commercial production of semiconductor chips. The higher cost of electroplating compared to sputtering renders use of pure elemental Ni commercially undesirable.

While the use of a metal compound such as a Ni—Si alloy or a Ni—W alloy or Ni—V alloy enables use of sputtering for formation of the underbump metallic layer, such metal compounds invariably necessitate the use of a wetting layer. Also, Sn-based solder reacts with only the Ni-component of the alloy and not the Si or W or V component. As such, when the Ni is consumed by Sn, the remaining alloy is enriched in Si or W or V and this will lead to reliability concerns.

In view of the above, there exists a need for an underbump metallurgy structure that results in consumption of only a limited quantity of material due to interaction with a C4 ball, and requires as few processing steps as possible, and provides a stable structure in which consumption of material does not continue with usage at a high temperature.

Further, there exists a need for methods of forming such an underbump metallurgy structure in an economical manner, while minimizing process complexity.

### SUMMARY OF THE INVENTION

The present invention addresses the needs described above by providing a method of forming an underbump metallurgy structure in which a non-magnetic Ni—Cu alloy is deposited on a metallic adhesion layer by sputtering, in which the composition of the Ni—Cu alloy is selected to minimize reaction with a C4 ball.

In the present invention, a metallic adhesion layer is formed on a last level metal plate exposed in an opening of a passivation layer. A Ni—Cu alloy in which the weight percentage of Ni is from about 50% to about 70% is deposited by sputtering onto the metallic adhesion layer to form an underbump metallic layer. Optionally, a wetting layer comprising Cu or Au may be deposited by sputtering. A C4 ball is applied to a surface of the underbump metallic layer comprising the Ni—Cu alloy or the wetting layer for C4 processing. The sputter deposition of the Ni—Cu alloy offers economic advantages relative to known methods in the art since the Ni—Cu alloy in the composition of the present invention is non-magnetic and easy to sputter, and the consumption of the inventive Ni—Cu alloy is limited during C4 processing.

According to an aspect of the present invention, a method of forming a semiconductor structure is provided, which comprises:

forming a metallic adhesion layer directly on a semiconductor chip;

forming a Cu—Ni alloy layer directly on the metallic adhesion layer by sputtering, wherein a weight percentage of Ni in the Cu—Ni alloy layer is from about 50% to about 70%; and

applying a C4 ball on directly on the Cu—Ni alloy layer.

According to another aspect of the present invention, another method of forming a semiconductor structure is provided, which comprises:

forming a metallic adhesion layer directly on a semiconductor chip;

forming a Cu—Ni alloy layer directly on the metallic adhesion layer by sputtering, wherein a weight percentage of Ni in the Cu—Ni alloy is from about 50% to about 70%;

forming a wetting layer directly on the Cu—Ni alloy layer, wherein the wetting layer comprises pure Cu or pure Au or pure Ag; and

applying a C4 ball directly on the wetting layer.

### BRIEF DESCRIPTION OF THE DRAWINGS

FIG. 1 shows a vertical cross-sectional view of a first exemplary semiconductor structure according to a first embodiment of the present invention prior to dicing and application of a C4 ball.

FIG. 2 shows a phase diagram of the Cu—Ni alloy system.

FIG. 3 shows a vertical cross-sectional view of the first exemplary semiconductor structure according to the first embodiment of the present invention after dicing and application of a C4 ball and prior to a reflow.

FIG. 4 shows a vertical cross-sectional view of the first exemplary semiconductor structures after the reflow.

FIGS. 5 and 6 shows sequential vertical cross-sectional views of a second exemplary semiconductor structure according to a second embodiment of the present invention prior to a reflow, and after the reflow, respectively.

FIGS. 7 and 8 show scanning electron micrographs (SEMs) of a physical exemplary semiconductor structure according to the second embodiment of the present invention after a reflow.

### DETAILED DESCRIPTION OF THE INVENTION

As stated above, the present invention relates to underbump metallurgy (UBM) employing a sputter-deposited nickel copper alloy and structure and methods thereof, which are now described in detail with accompanying figures.

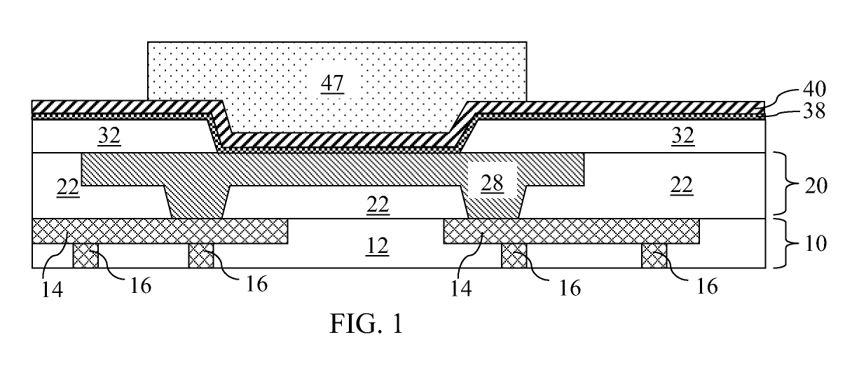

Referring to FIG. 1, a first exemplary semiconductor structure comprises a back-end-of-line (BEOL) interconnect structure 10, a last level interconnect structure 20, and a dielectric passivation layer 32 that are formed on a semiconductor substrate (not shown). Semiconductor devices (not shown) are formed on the semiconductor substrate by employing semiconductor manufacturing processes known in the art. Typically, additional BEOL interconnect structures (not shown) are present between the semiconductor devices and the BEOL interconnect structure 10. The additional BEOL interconnect structures facilitate wiring of the semiconductor devices.

The BEOL interconnect structure 10 includes a back-end-of-line (BEOL) dielectric layer 12, back-end-of-line (BEOL) metal lines 14, and back-end-of-line (BEOL) metal vias 16. The BEOL metal lines 14 and the BEOL metal vias 16 are embedded in the BEOL dielectric layer 12. The BEOL dielectric layer may comprise silicon oxide or a low-k dielectric material known in the art. The BEOL metal lines 14 and the BEOL metal via 16 comprise a conductive metal such as Cu, and are formed by methods well known in the art.

The last level interconnect structure 20 includes a last level dielectric layer 22 and a last level metal plate 28. The last level dielectric layer 22 comprises a dielectric material such as silicon oxide. The last level metal plate 28 comprises a metal such as aluminum. Typically, the last level metal plate 28 is integrally formed with at least one via that electrically connects the last level metal plate 28 with the BEOL metal lines 14.

The dielectric passivation layer 32 comprises an impervious dielectric material that blocks ingress of moisture and oxygen into the last level interconnect structure 20. Exemplary impervious dielectric materials include silicon nitride. The dielectric passivation layer 32 may be a homogeneous layer comprising the impervious dielectric material, or may be a stack of multiple dielectric material layers including an impervious dielectric material layer. The thickness of the dielectric passivation layer 32 may be from about 2.0 μm to about 40 μm, and typically from about 4.0 μm to about 20 μm.

The dielectric passivation layer 32 has an opening that exposes a top surface of the last level metal plate 28. Typically, the dimension of the opening, e.g., a diameter of the opening, is from about 50 μm to about 100 μm. The opening is formed by lithographic patterning of a photosensitive resist that is removed after patterning of the opening, or a photosensitive polyimide which may form a part of the passivation layer 32.

A metallic adhesion layer 38 is deposited by chemical vapor deposition (CVD) or physical vapor deposition (PVD), i.e., sputtering. The metallic adhesion layer 38 comprises a metallic material that provides good adhesion to underlying structures including the last level metal plate 28 and the dielectric passivation layer 32. Exemplary materials for the metallic adhesion layer 38 comprise Ti, TiN, and TiW. The thickness of the metallic adhesion layer 38 may be from about 100 nm to about 500 nm, although lesser and greater thicknesses are also explicitly contemplated herein.

A Cu—Ni alloy layer 40 is formed directly on the metallic adhesion layer 38 by sputtering, i.e., physical vapor deposition. The semiconductor substrate, on which the BEOL interconnect structure 10, the last level interconnect structure 20, the dielectric passivation layer 32, and the metallic adhesion layer 38 are located, is placed in a vacuum chamber (not shown) having a sputter target (not shown). The sputter target contains a Cu—Ni alloy having a weight percentage of Ni from about 50% to about 70%. The material in the sputter target is sputtered onto the metallic adhesion layer 38 in an ultra-high vacuum (UHV) environment. Tools configured to accommodate a sputtering target and provide sputtering of the material in the sputtering target onto a substrate surface in a UHV environment are commercially available.

The weight percentage of Ni from about 50% to about 70% in the Cu—Ni alloy has been empirically selected based on empirical data from experiments leading to the present invention and consideration for providing a non-magnetic alloy for ease of the sputtering process employed in the formation of the Cu—Ni alloy layer 40.

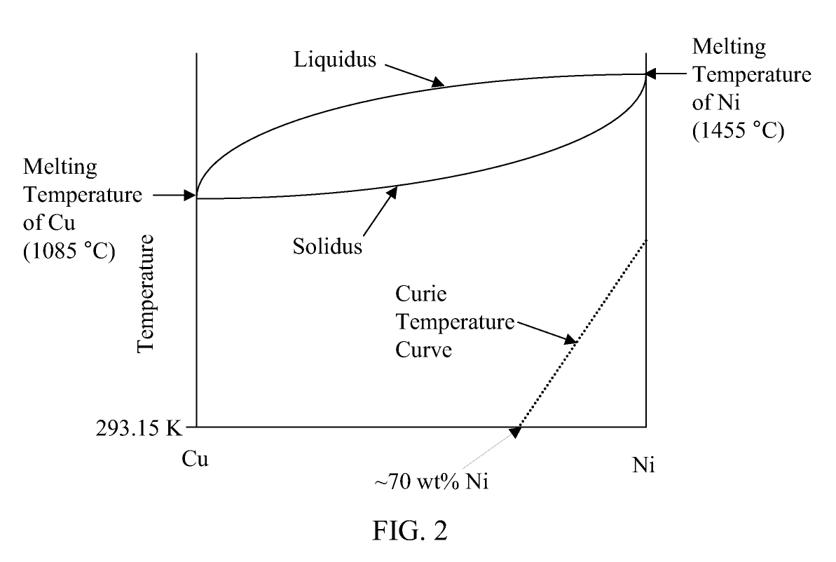

Referring to FIG. 2, a binary phase diagram of a Cu—Ni alloy system shows an isomorphous system in which Cu and Ni form a continuous solution over the entire concentration range. The Cu—Ni alloy system forms a face-centered cubic (f.c.c.) structure below a solidus of the binary phase diagram. The Cu—Ni alloy system displays a concentration dependent Curie temperature, below which the Cu—Ni alloy of a given concentration is ferromagnetic. The higher the weight percentage of Ni, the higher Curie temperature of the Cu—Ni alloy. At and above room temperature, (i.e., 293.15K, which is 20° C.), a Cu—Ni alloy is non-magnetic if the weight percentage of Ni is below 70%. By selecting a weight percentage of Ni about 70% or less, the Cu—Ni alloy is non-magnetic at or above room temperature. The material of the sputter target, which is a Cu—Ni alloy with a weight percentage of Ni about 70% or less, is thus non-magnetic, and complications of a sputtering process that would be encountered during a sputter deposition of a magnetic alloy is avoided. The lower bound of the weight percentage range for Ni is determined by a need to limit the consumption of the Cu—Ni alloy during a reflow, as will be discussed below.

Referring back to FIG. 1, the thickness of the Cu—Ni alloy layer 40 may be from about 1.0 μm to about 4.0 μm, and preferably from about 1.2 μm to about 3.0 μm, and more preferably from about 1.5 μm to about 2.5 μm. A photoresist 47 is applied over the Cu—Ni alloy layer 40 and lithographically patterned so that the region above the opening in the passivation layer 32 is covered with the photoresist 47, while the photoresist 47 is removed from an area outside the opening. The exposed portions of the Cu—Ni layer 40 and the metallic adhesion layer 38 outside the area of the photoresist 47 is etched. The etch may be an anisotropic etch, and may be selective to the passivation layer 32. The photoresist 47 is subsequently removed.

Typically, the semiconductor substrate and the structures thereupon, which include the BEOL interconnect structure 10, the last level interconnect structure 20, the dielectric passivation layer 32, the metal adhesion layer 38, and the Cu—Ni alloy layer 40, are diced so that multiple semiconductor chips are separated along dicing channels. Typically, each semiconductor chip is identical to the rest of the semiconductor chips. Each semiconductor chip comprises portions of the BEOL interconnect structure 10, the last level interconnect structure 20, the dielectric passivation layer 32, the metal adhesion layer 38, and the Cu—Ni alloy layer 40 within dicing channels that define boundaries between adjacent semiconductor chips.

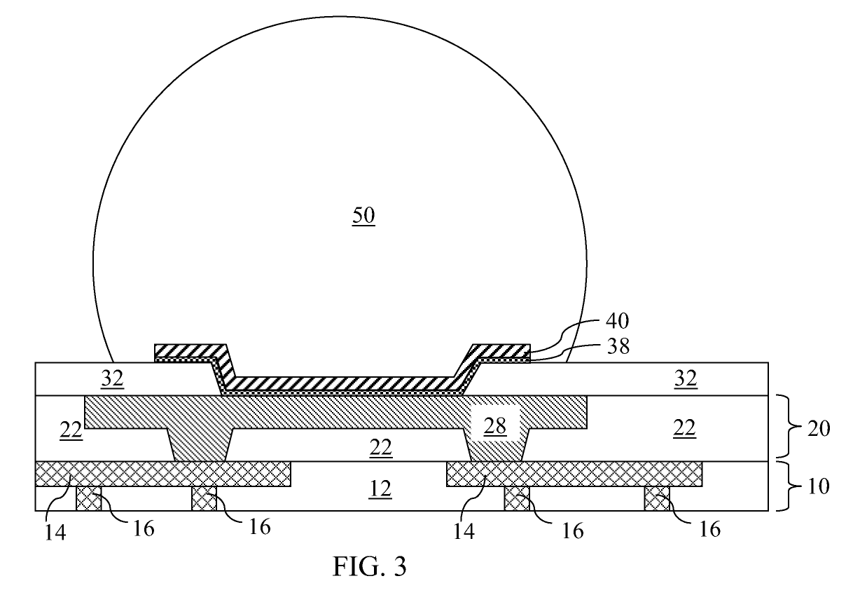

Referring to FIG. 3, a C4 ball 50 is applied to each C4 pad within a semiconductor chip. Each C4 pad comprises a metal adhesion layer 38 and a Cu—Ni alloy layer 40. The C4 ball 50 directly contacts a top surface of the Cu—Ni alloy layer 40. The C4 ball may directly contact a portion of the passivation layer 32 along the periphery of the stack of the metal adhesion layer 38 and the Cu—Ni alloy layer 40.

The C4 ball 50 comprises a lead-free solder. For example, the C4 ball may comprise a Sn—Cu alloy, a Sn—Ag alloy, or a Sn—Cu—Ag alloy. In case Cu is present, the concentration of Cu is about 0.7 atomic percent. In case Ag is present, the concentration of Ag is from about 0.5 atomic percent to about 3.5 atomic percent. The diameter of the C4 ball, as measured in the largest horizontal cross-section of the C4 ball 50, may be from about 50 μm to about 120 μm, although lesser and greater diameters of the C4 ball are also contemplated herein.

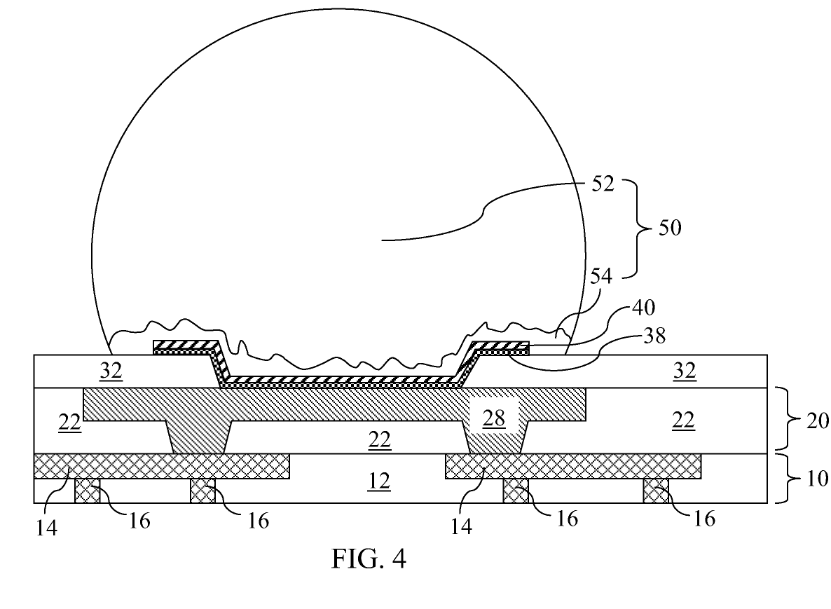

Referring to FIG. 4, the C4 ball 50 is “reflowed” to enhance adhesion to the Cu—Ni alloy layer 40. The reflow of the C4 ball 50 is facilitated by subjecting the C4 ball 50 and the Cu—Ni alloy layer 40 to an anneal at an elevated temperature from about 210° C. to about 260° C., and typically from about 220° C. to about 250° C. The duration of the anneal at the elevated temperature may be from about 1 hour to about 24 hours, and typically from 2 hours to about 12 hours. During the reflow, a portion of the Cu—Ni alloy layer 40 reacts with the material of the C4 ball 50, which is the Sn—Cu alloy, the Sn—Ag alloy, or the Sn—Cu—Ag alloy. Cu atoms and Ni atoms in a top portion of the Cu—Ni alloy layer 40 diffuse into the C4 ball 50 to form a Cu—Ni alloy diffused solder region 54 within the C4 ball 50. In other words, a portion of the C4 ball 50 that adjoins the Ni—Cu alloy layer 40 reacts with solder to form a Cu—Ni alloy diffused solder region 54, which comprises a Cu—Ni—Sn alloy, a Cu—Ni—Ag alloy, or a Ni—Cu—Sn—Ag alloy. The rest of the C4 ball 50 is herein referred to as an original composition solder region 52, which has the same composition as the C4 ball 50 prior to the reflow. The original composition solder region 52 and the Cu—Ni alloy diffused solder region 54 collectively constitute the C4 ball 50 after the reflow.

The amount of consumption of the Cu—Ni alloy layer 40, depends not only on the reflow conditions but also on the composition of the Cu—Ni alloy layer 40. In the course of research leading to the present invention, it has been observed that a low weight percentage of Ni in general contributes to a high consumption rate of the Cu—Ni alloy layer 40. Weight percentage of Ni about 50% or greater maintains the consumption of the Cu—Ni alloy layer 40 during the reflow to a manageable level. Combined with the limitation on the weight percentage of Ni to keep the Cu—Ni alloy layer 40 non-magnetic, this results in an optimal range of the weight percentage of Ni from about 50% to about 70%. A preferred range for the weight percentage of Ni that reduces the amount consumption of the Cu—Ni alloy layer 40 is from about 50% to about 70%. In this range, consumption of about 1.0 μm to about 1.2 μm of the Cu—Ni alloy layer 40 after 10 repeated application of reflow conditions at 245° C. has been observed. Most preferably, the weight percentage of Ni that reduces the amount consumption of the Cu—Ni alloy layer 40 is from about 60% to about 70%, in which case the thickness of consumed amount of the Cu—Ni alloy layer 40 may be less than 1.0 μm.

Thus, the first embodiment of the present invention provides a method for forming a reflowed C4 ball by employing a simple and economical process of sputter deposition of a non-magnetic alloy layer, which is the Cu—Ni alloy layer 40, without requiring an electroplating process or a sputter deposition process for formation of a wetting layer.

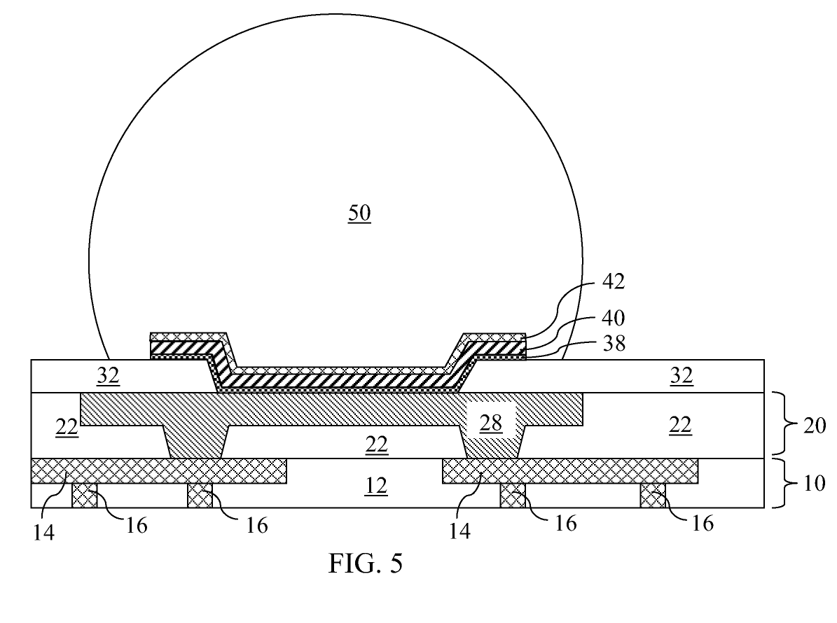

Referring to FIG. 5, a second exemplary semiconductor structure according to a second embodiment of the present invention employs the structures and methods of the first exemplary semiconductor structure up to the step of formation of the Cu—Ni alloy layer 40. Before applying the photoresist 47 (See FIG. 1), a wetting layer 42 is formed directly on the Cu—Ni alloy layer 40. The wetting layer 42 comprises an elemental metal. For example, the wetting layer 42 may comprise pure Cu or pure Au or pure Ag. The wetting layer 42 may be deposited by electroplating, or preferably, by sputter deposition to reduce the processing cost. The thickness of the wetting layer 42 may be from about 0.3 μm to about 0.8 μm, and preferably from about 0.4 μm to about 0.6 μm, although lesser and greater thicknesses are also contemplated herein.

A photoresist (not shown) is applied over the Cu—Ni alloy layer 40 and lithographically patterned as in the first embodiment. The wetting layer 42 is patterned in the same shape as the Cu—Ni layer 40 and the metallic adhesion layer 38 employing the same type of etch as in the first embodiment. The semiconductor substrate and the structures thereupon are diced so that multiple semiconductor chips are separated along dicing channels. Each semiconductor chip comprises portions of the BEOL interconnect structure 10, the last level interconnect structure 20, the dielectric passivation layer 32, the metal adhesion layer 38, the Cu—Ni alloy layer 40, and the wetting layer 42 within dicing channels that define boundaries between adjacent semiconductor chips.

A C4 ball 50 is applied to each C4 pad within a semiconductor chip. Each C4 pad comprises the wetting layer 42, the metal adhesion layer 38 and the Cu—Ni alloy layer 40 that are patterned around the opening in the dielectric passivation layer 32. The C4 ball 50 directly contacts a top surface of the wetting layer 42. The C4 ball 50 may directly contact a portion of the passivation layer 32 along the periphery of the stack of the metal adhesion layer 38, the Cu—Ni alloy layer 40, and the wetting layer 42.

The C4 ball 50 comprises a lead-free solder as in the first embodiment. For example, the C4 ball may comprise a Sn—Cu—Ag alloy, in which the concentration of Cu is about 0.7 atomic percent and the concentration of Ag is from about 0.5 atomic percent to about 3.5 atomic percent. The diameter of the C4 ball, as measured in the largest horizontal cross-section of the C4 ball 50, may be from about 50 μm to about 120 μm, although lesser and greater diameters of the C4 ball are also contemplated herein.

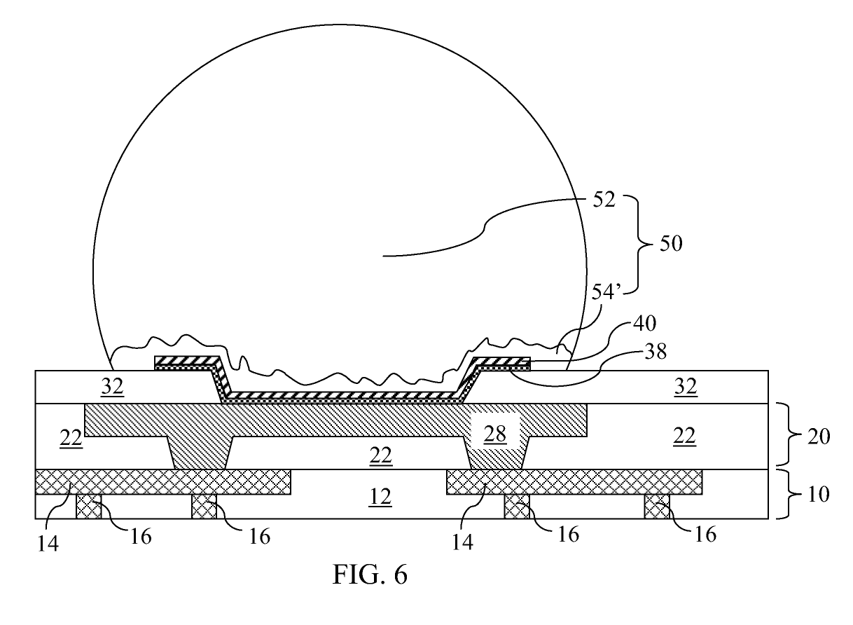

Referring to FIG. 6, the C4 ball 50 is “reflowed” to enhance adhesion to the Cu—Ni alloy layer 40. The reflow of the C4 ball 50 is facilitated by subjecting the C4 ball 50 and the Cu—Ni alloy layer 40 to an anneal at an elevated temperature, which may have the same processing conditions as in the first embodiment. Typically, the material in wetting layer 42, which is typically Cu or Au, is completely consumed during the reflow since Cu or Au readily reacts with the material of the C4 ball 50, which is the Sn—Cu—Ag alloy. A portion of the Cu—Ni alloy layer 40 also reacts with the material of the C4 ball 50. The material of the wetting layer 42 and the material that diffuse out from the Cu—Ni alloy layer 40, i.e., Cu atoms and the Ni atoms from a top portion of the Cu—Ni alloy layer 40, react with the material of the C4 ball 50 to form a Cu—Ni alloy diffused solder region 54′ within the C4 ball 50. In case the wetting layer 42 comprises Cu, the Cu—Ni alloy diffused solder region 54′ comprises the original material of the C4 ball 50 and Cu and Ni. In case the wetting layer 42 comprises Au, the Cu—Ni alloy diffused solder region 54′ comprises the original material of the C4 ball 50, Cu, Ni, and Au.

As in the first embodiment, a portion of the C4 ball 50 that adjoins the Ni—Cu alloy layer 40 react with each other to form a Cu—Ni alloy diffused solder region 54′, which comprises a Cu—Ni—Sn alloy, a Cu—Ni—Ag alloy, or a Ni—Cu—Sn—Ag alloy depending on the composition of the wetting layer 42. The rest of the C4 ball 50 is herein in referred to as an original composition solder region 52, which has the same composition as the C4 ball 50 prior to the reflow. As in the first embodiment, the original composition solder region 52 and the Cu—Ni alloy diffused solder region 54′ collectively constitute the C4 ball 50 after the reflow.

The same criteria are used to minimize the consumption of the Cu—Ni alloy layer 40 during the reflow as in the first embodiment. Weight percentage of Ni from about 50% to about 70% may be employed to practice the present invention, in which the range of the weight percentage of Ni from about 50% to about 70% is preferable, and the range of the weight percentage of Ni from about 60% to about 70% is more preferable.

Thus, the second embodiment of the present invention provides a method for forming a reflowed C4 ball by employing a simple and economical process of sputter deposition of a non-magnetic alloy layer, which is the Cu—Ni alloy layer 40. The second embodiment requires formation of a wetting layer 42 by electroplating, or preferably, by a sputter deposition.

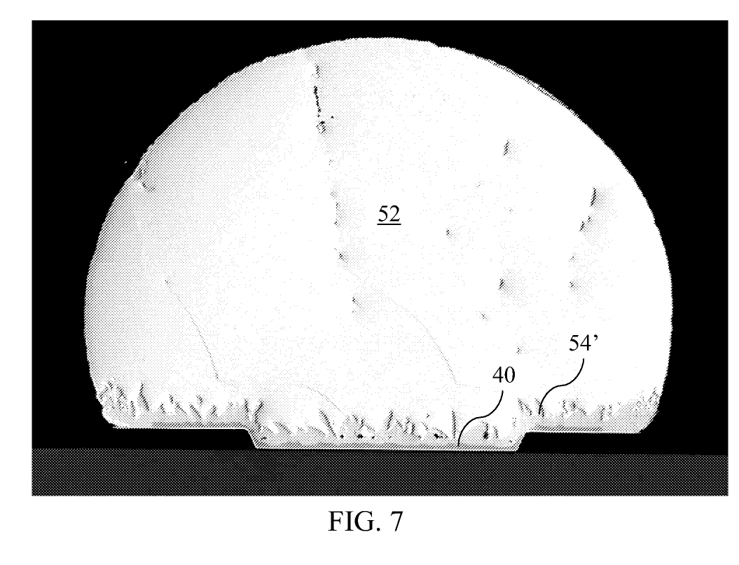

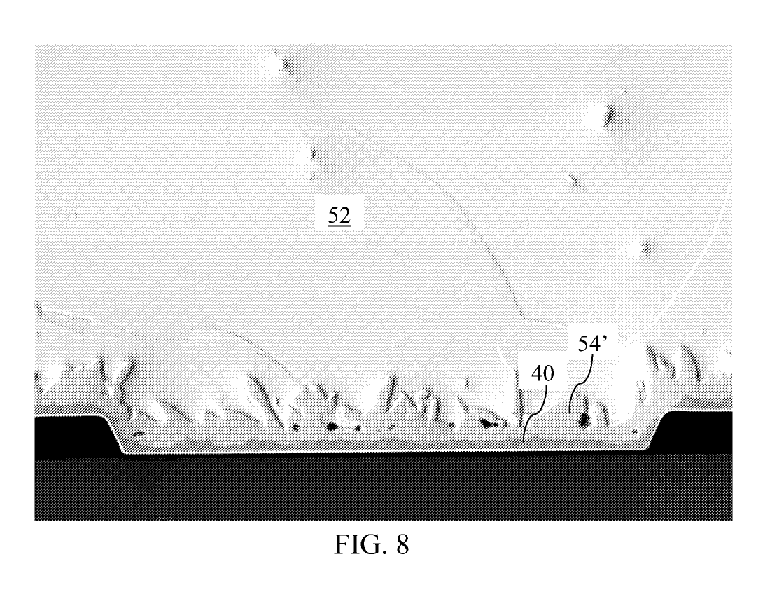

FIG. 7 shows a scanning electron micrograph (SEM) of a vertical cross-section of a physical exemplary semiconductor structure according to the second embodiment of the present invention after a reflow and a high temperature storage. FIG. 8 is a higher magnification view of the SEM in FIG. 7 showing detailed features. In this example, a metallic adhesion layer (shown by a thin white line directly below a Cu—Ni alloy layer 40) comprises TiW and has a thickness of about 160 nm. The Cu—Ni alloy layer 40, which was deposited by sputter deposition in a vacuum chamber and has a weight percentage of Ni of about 60%, is located directly on the metallic adhesion layer. Prior to the reflow, the physical exemplary semiconductor structure contained a wetting layer comprising Cu and having a thickness of about 500 nm. The reflow was performed at 245° C. for an extended duration (10 times the duration of a normal reflow) to increase reaction of the Cu—Ni alloy layer 40, and the physical exemplary semiconductor structure was stored at 170° C. for 258 hours to simulate usage of the physical exemplary semiconductor structure for the duration of a lifetime of a semiconductor chip.

The material of the wetting layer and the material of a top portion of the Cu—Ni alloy layer 40 diffused into the C4 ball to form a Cu—Ni alloy diffused solder region 54′, which comprises a mixture of the original material of the C4 ball and Cu and Ni. The original composition solder region 52 above the Cu—Ni alloy diffused solder region 54′ comprises the original material of the C4 ball prior to the reflow.

Due to statistical nature of consumption of the Cu—Ni alloy layer 40 during the reflow, the interface between the Cu—Ni alloy layer 40 and the Cu—Ni alloy diffused solder region 54′ has variations in height. However, it is noteworthy that the Cu—Ni alloy layer 40 is substantially contiguous across the SEM. In other words, the stack of the 500 nm of wetting layer comprising Cu and the Cu—Ni alloy layer 40 comprising 60% of Ni in weight percentage is sufficient to provide all the material to diffuse into the C4 ball after a reflow for an extended time and a high temperature storage that simulates end-of-life aging of the C4 ball. It is noted that consumption of Cu is rapid in such conditions, i.e., up to 5 μm of Cu consumption under similar conditions is known. The limited consumption of the Cu—Ni alloy layer 40 is due to the composition of the Cu—Ni alloy layer 40 comprising 60% of Ni in weight percentage. Cu—Ni alloy consumption less than 1.0 μm in thickness is achieved under normal reflow conditions when a Cu—Ni alloy layer has an optimized weight percentage of Ni, for example, in the range from about 60% to about 70%.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of forming a semiconductor structure comprising:
forming a metallic adhesion layer directly on a semiconductor chip;
forming a Cu—Ni alloy layer directly on said metallic adhesion layer by sputtering, wherein a weight percentage of Ni in said Cu—Ni alloy layer is from about 50% to about 70%; and
applying a C4 ball on directly on said Cu—Ni alloy layer.

2. The method of claim 1, wherein said semiconductor chip comprises:
a last level interconnect structure including a last level metal plate; and
a dielectric passivation layer having an opening therein, wherein said metallic adhesion layer vertically abuts said last level metal plate within said opening.

3. The method of claim 1, wherein said metallic adhesion layer comprises Ti, TiN, or TiW, and has a thickness from about 100 nm to about 500 nm.

4. The method of claim 1, wherein said weight percentage of Ni in said Cu—Ni alloy layer is from about 50% to about 70%.

5. The method of claim 4, wherein said weight percentage of Ni in said Cu—Ni alloy layer is from about 60% to about 70%.

6. The method of claim 1, wherein a thickness of said Cu—Ni alloy layer is from about 1.0 μm to about 4.0 μm.

7. The method of claim 1, wherein said Cu—Ni alloy layer is deposited on said metallic adhesion layer in a vacuum chamber by sputtering of material from a sputter target containing a Cu—Ni alloy having a weight percentage of Ni from about 50% to about 70%.

8. The method of claim 1, wherein said C4 ball comprises a Sn—Cu alloy, a Sn—Ag alloy, or a Sn—Cu—Ag alloy.

9. The method of claim 8, wherein a concentration of Cu is about 0.7 atomic percent and a concentration of Ag is from about 0.5 atomic percent to about 3.5 atomic percent.

10. The method of claim 1, further comprising reflowing said C4 ball at a temperature from about 210° C. to about 260° C.

11. A method of forming a semiconductor structure comprising:
forming a metallic adhesion layer directly on a semiconductor chip;
forming a Cu—Ni alloy layer directly on said metallic adhesion layer by sputtering, wherein a weight percentage of Ni in said Cu—Ni alloy is from about 50% to about 70%;
forming a wetting layer directly on said Cu—Ni alloy layer, wherein said wetting layer comprises pure Cu or pure Au or pure Ag; and
applying a C4 ball directly on said wetting layer.

12. The method of claim 11, wherein said semiconductor chip comprises:
a last level interconnect structure including a last level metal plate; and
a dielectric passivation layer having an opening therein, wherein said metallic adhesion layer vertically abuts said last level metal plate within said opening.

13. The method of claim 11, wherein said metallic adhesion layer comprises Ti, TiN, or TiW, and has a thickness from about 100 nm to about 500 nm.

14. The method of claim 11, wherein said weight percentage of Ni in said Cu—Ni alloy layer is from about 50% to about 70%.

15. The method of claim 14, wherein said weight percentage of Ni in said Cu—Ni alloy layer is from about 60% to about 70%.

16. The method of claim 11, wherein a thickness of said Cu—Ni alloy layer is from about 1.0 μm to about 4.0 μm.

17. The method of claim 11, wherein said Cu—Ni alloy layer is deposited on said metallic adhesion layer in a vacuum chamber by sputtering of material from a sputter target containing a Cu—Ni alloy having a weight percentage of Ni from about 50% to about 70%.

18. The method of claim 11, wherein said wetting layer has a thickness from about 0.3 μm to about 0.8 μm.

19. The method of claim 11, further comprising reflowing said C4 ball at a temperature from about 210° C. to about 260° C.

20. The method of claim 19, wherein said wetting layer reacts with said C4 ball during said reflowing, and wherein less than 1.0 μm of said Cu—Ni alloy layer is consumed by reaction with said C4 ball during said reflowing.
